(19) United States
(12) Patent Application Publication
(10) Pub. No.: US 2017/0256706 A1
(43) Pub. Date: Sep. 7, 2017

(54) MAGNETIC STORAGE DEVICE AND MANUFACTURING METHOD OF MAGNETIC STORAGE DEVICE

(71) Applicant: KABUSHIKI KAISHA TOSHIBA, Tokyo (JP)

(72) Inventors: Masaru TOKO, Seoul (KR); Keiji HOSOTANI, Seoul (KR); Hisanori AIKAWA, Seoul (KR); Tatsuya KISHI, Seongnam-si (KR)

(73) Assignee: KABUSHIKI KAISHA TOSHIBA, Tokyo (JP)

(21) Appl. No.: 15/261,741

(22) Filed: Sep. 9, 2016

Related U.S. Application Data
(60) Provisional application No. 62/304,064, filed on Mar. 4, 2016.

(51) Int. Cl. H01L 43/10; H01L 43/12; H01L 43/08; G11C 11/16; H01L 43/02

(52) U.S. Cl. CPC H01L 43/10; G11C 11/161; H01L 43/02; H01L 43/08; H01L 43/12; G11C 11/165

(57) ABSTRACT

According to one embodiment, a magnetic storage device includes a first and a second magnetoresistive effect element, which are disposed in an arrangement pattern including a plurality of arrangement areas, and in each of which a second ferromagnetic layer and a third ferromagnetic layer are antiferromagnetically coupled. A magnetization orientation of the third ferromagnetic layer of the first magnetoresistive effect element is antiparallel to a magnetization orientation of the third ferromagnetic layer of the second magnetoresistive effect element. The first magnetoresistive effect element is disposed in an arrangement area randomly positioned with respect to an arrangement area in which the second magnetoresistive effect element is disposed.

### CROSS-REFERENCE TO RELATED APPLICATIONS

This application claims the benefit of U.S. Provisional Application No. 62/304,064, filed Mar. 4, 2016, the entire contents of which are incorporated herein by reference.

### FIELD

Embodiments described herein relate generally to a magnetic storage and a manufacturing method of a magnetic storage device.

### BACKGROUND

As a storage device included in a memory system, there is known a magnetic storage device (MRAM: Magnetoresistive Random Access Memory) which employs a magnetoresistive effect element as a memory element.

The magnetic storage device includes, for example, a magnetoresistive effect element as a memory element. The magnetoresistive effect element includes a storage layer with magnetization, a reference layer, and a tunnel barrier layer. The magnetoresistive effect element can store data semipermanently, for example, by setting the magnetization orientation of the storage layer to be either parallel or antiparallel to the magnetization orientation of the reference layer. The magnetic storage device sets the magnetization orientation of the storage layer, for example, by causing a magnetization reversal current to flow through the magnetoresistive effect element.

### BRIEF DESCRIPTION OF THE DRAWINGS

FIG. 1 is a block diagram illustrating the configuration of a magnetic storage device according to an embodiment.

FIG. 2 is a cross-sectional view illustrating the configuration of a memory cell of the magnetic storage device according to the embodiment.

FIG. 3 is a cross-sectional view illustrating the configuration of a magnetoresistive effect element of the magnetic storage device according to the embodiment.

FIG. 4 is a perspective view illustrating the relationship between the arrangement and magnetization orientations of the magnetoresistive effect elements of the magnetic storage device according to the embodiment.

FIG. 5 is a perspective view illustrating a part of a manufacturing method of the magnetic storage device according to the embodiment.

FIG. 6 is a perspective view illustrating a part of the manufacturing method of the magnetic storage device according to the embodiment.

FIG. 7 is a perspective view illustrating a part of the manufacturing method of the magnetic storage device according to the embodiment.

FIG. 8 is a perspective view illustrating a part of the manufacturing method of the magnetic storage device according to the embodiment.

FIG. 9 is a perspective view illustrating a part of the manufacturing method of the magnetic storage device according to the embodiment.

FIG. 10 is a diagram illustrating characteristics of the magnetoresistive effect element of the magnetic storage device according to the embodiment.

FIG. 11 is a flowchart illustrating an evaluation method of the advantageous effects of the magnetic storage device according to the embodiment.

FIG. 12 is a diagram illustrating an evaluation result of the advantageous effects of the magnetic storage device according to the embodiment.

FIG. 13 is a schematic view illustrating the configuration of a magnetic storage device according to a first modification of the embodiment.

FIG. 14 is a diagram illustrating characteristics of a test pattern of the magnetic storage device according to the first modification of the embodiment.

FIG. 15 is a diagram illustrating characteristics of test patterns of the magnetic storage device according to the first modification of the embodiment.

FIG. 16 is a schematic view illustrating the configuration of a magnetic storage device according to a second modification of the embodiment.

FIG. 17 is a cross-sectional view illustrating the configuration of a new magnetoresistive effect element of the magnetic storage device according to the second modification of the embodiment.

FIG. 18 is a schematic view illustrating the characteristics of the new magnetoresistive effect element of the magnetic storage device according to the second modification of the embodiment.

FIG. 19 is a diagram illustrating the characteristics of the new magnetoresistive effect elements of the magnetic storage device according to the second modification of the embodiment.

### DETAILED DESCRIPTION

In general, according to one embodiment, a magnetic storage device includes a substrate, and a first magnetoresistive effect element and a second magnetoresistive effect element. Each of the first magnetoresistive effect element and the second magnetoresistive effect element includes a first ferromagnetic layer, a second ferromagnetic layer, a third ferromagnetic layer, a first nonmagnetic layer provided between the first ferromagnetic layer and the second ferromagnetic layer, and a second nonmagnetic layer provided between the second ferromagnetic layer and the third ferromagnetic layer and configured to antiferromagnetically couple the second ferromagnetic layer and the third ferromagnetic layer. The first magnetoresistive effect element and the second magnetoresistive effect element are disposed, above the substrate, in an arrangement pattern including a plurality of arrangement areas. A magnetization orientation of the third ferromagnetic layer of the first magnetoresistive effect element is antiparallel to a magnetization orientation of the third ferromagnetic layer of the second magnetoresistive effect element. The first magnetoresistive effect element is disposed in an arrangement are randomly positioned with respect to an arrangement area in which the second magnetoresistive effect element is disposed.

Hereinafter, embodiments will be described with reference to the accompanying drawings. In the description below, structural elements having substantially the same functions and structures are denoted by like reference signs, and an overlapping description is given only where necessary. In addition, embodiments to be described below illustrate, by way of example, devices or methods for embodying technical concepts of the embodiments, and the technical concepts of the embodiments do not specifically restrict the material, shape, structure, arrangement, etc. of structural components to those described below. Various changes may be made in the technical concepts of the embodiments within the scope of the claims.

### 1. Embodiment

A magnetic storage device according to an embodiment is described.

1.1. Re: Configuration

1.1.1. Re: Configuration of Magnetic Storage Device

To begin with, the configuration of the magnetic storage device according to the embodiment is described. The magnetic storage device according to the embodiment is a magnetic storage device by a vertical magnetization method, which uses, for example, a magnetoresistive effect element (MTJ (Magnetic Tunnel Junction) element) as a memory element.

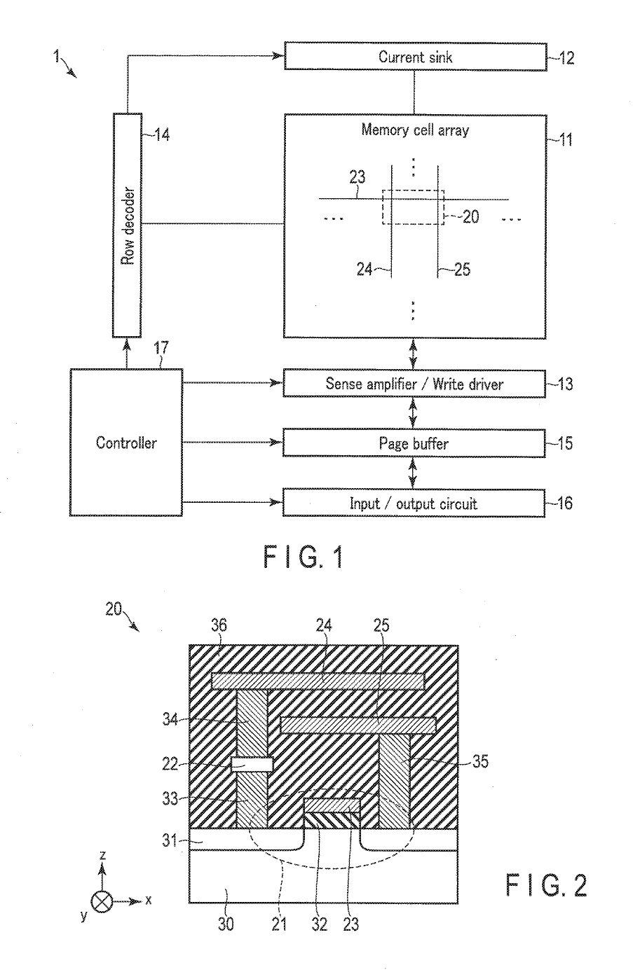

FIG. 1 is a block diagram illustrating the configuration of a magnetic storage device 1 according to the embodiment. As illustrated in FIG. 1, the magnetic storage device 1 includes a memory cell array 11, a current sink 12, a sense amplifier and write driver (SA/WD) 13, a row decoder 14, a page buffer 15, an input/output circuit 16, and a controller 17.

The memory cell array 11 includes a plurality of memory cells 20 which are associated with rows and columns. In addition, the memory cells 20 on an identical row are connected to an identical word line 23, and both ends of the memory cells 20 on an identical column are connected to an identical bit line 24 and an identical source line 25.

The current sink 12 is connected to the bit line 24 and source line 25. The current sink 12 sets the bit line 24 or source line 25 at a ground potential in operations such as data write and read.

The SA/WD 13 is connected to the bit line 24 and source line 25. The SA/WD 13 supplies an electric current to the memory cell 20 of an operation target via the bit line 24 and source line 25, and executes data write to the memory cell 20. In addition, the SA/WD 13 supplies an electric current to the memory cell 20 of the operation target via the bit line 24 and source line 25, and executes data read from the memory cell 20. To be more specific, the write driver of the SA/WD 13 executes data write to the memory cell 20, and the sense amplifier of the SA/WD 13 executes data read from the memory cell 20.

The row decoder 14 is connected to the memory cell array 11 via the word line 23. The row decoder 14 decodes a row address which designates the row direction of the memory cell array 11. In addition, the row decoder 14 selects the word line 23 in accordance with the decoded result, and applies to the selected word line 23 a voltage which is necessary for operations such as data write and read.

The page buffer 15 temporarily stores, in units of data called “page”, data which is to be written in the memory cell array 11, and data which was read from the memory cell array 11.

The input/output circuit 16 transmits various signals, which were received from the outside of the magnetic storage device 1, to the controller 17 and page buffer 15, and transmits various pieces of information from the controller 17 and page buffer 15 to the outside.

The controller 17 is connected to the current sink 12, SA/WD 13, row decoder 14, page buffer 15, and input/output circuit 16. The controller 17 controls the current sink 12, SA/WD 13, row decoder 14 and page buffer 15 in accordance with various signals which the input/output circuit 16 received from the outside of the magnetic storage device 1.

1.1.2. Re: Configuration of Memory Cell

Next, the configuration of the memory cell of the magnetic storage device according to the embodiment is described with reference to FIG. 2. In the description below, a plane parallel to a semiconductor substrate 30 is defined as an xy plane, and an axis perpendicular to the xy plane is defined as a z axis. An x axis and a y axis are defined as axes which are perpendicular to each other in the xy plane. FIG. 2 is a cross-sectional view in a case where the memory cell 20 of the magnetic storage device 1 according to the embodiment is cut along the xz plane.

As illustrated in FIG. 2, the memory cell 20 is provided on the semiconductor substrate 30, and includes a cell transistor 21 and a magnetoresistive effect element 22. The cell transistor 21 functions as a switch which controls the supply and stop of an electric current at a time of writing and reading data to and from the magnetoresistive effect element 22. The magnetoresistive effect element 22 includes a plurality of stacked films, and the resistance value of the magnetoresistive effect element 22 can be switched between a low resistance state and a high resistance state by passing an electric current perpendicular to the film plane. The magnetoresistive effect element 22 functions as a memory element to which data can be written by a change of the resistance state of the magnetoresistive effect element 22, and the written data can be stored nonvolatilely and can be read.

The cell transistor 21 includes a gate functioning as the word line 23, and a pair of source/drain regions which are provided on a surface of the semiconductor substrate 30 at both ends of the gate in the x direction. The word line 23 is provided along the y direction via an insulation film 32 on the semiconductor substrate 30, and is commonly connected to, for example, the gates of cell transistors (not shown) of other memory cells which are arranged along the y direction. The word lines 23 are arranged, for example, in the x direction. One end of the cell transistor 21 is connected to a lower surface of the magnetoresistive effect element 22 via a contact 33 which is provided on the source region or drain region 31. A contact 34 is provided on an upper surface of the magnetoresistive effect element 22. The magnetoresistive effect element 22 is connected to the bit line 24 via the contact 34. The bit line 24 extends in the x direction, and is commonly connected to, for example, the other ends of magnetoresistive effect elements 22 (not shown) of other memory cells 24 which are arranged in the x direction. The other end of the cell transistor 21 is connected to the source line 25 via a contact 35 which is provided on the source region or drain region 31. The source line 25 extends in the x direction, and is commonly connected to, for example, the other ends of cell transistors (not shown) of other memory cells which are arranged in the x direction. The bit lines 24 and source lines 25 are arranged, for example, in the y direction. The bit line 24 is located, for example, above the source line 25. In the meantime, although illustration is omitted in FIG. 2, the bit line 24 and source line 25 are disposed, with mutual physical and electrical interferences being avoided. The cell transistor 21, magnetoresistive effect element 22, word line 23, bit line 24, source line 25 and contacts 33 to 35 are covered with an interlayer insulation film 36.

In the meantime, other magnetoresistive effect elements (not shown), which are arranged along the x direction or y direction in relation to the magnetoresistive effect element 22, are provided, for example, on the layer of the same level. Specifically, in the memory cell array 11, the plural magnetoresistive effect elements 22 are arranged, for example, in a direction of extension of the semiconductor substrate 30.

1.1.3. Re: Configuration of Magnetoresistive Effect Element

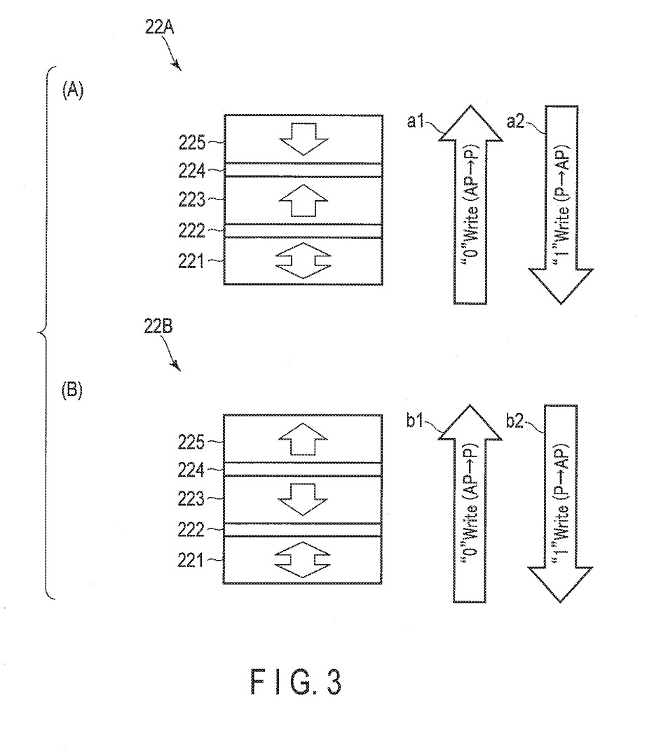

Next, the configuration of the magnetoresistive effect element of the magnetic storage device according to the embodiment is described with reference to FIG. 3. The magnetoresistive effect element 22 includes a first magnetoresistive effect element 22A and a second magnetoresistive effect element 22B. Part (A) of FIG. 3 is a cross-sectional view illustrating a cross section of the first magnetoresistive effect element of the magnetic storage device according to the embodiment, which is cut along a plane perpendicular to the xy plane.

As illustrated in part (A) of FIG. 3, the first magnetoresistive effect element 22A includes a storage layer 221, a tunnel barrier layer 222, a reference layer 223, a middle layer 224, and a shift cancelling layer 225.

In the first magnetoresistive effect element 22A, for example, a plurality of films, namely the storage layer 221, tunnel barrier layer 222, reference layer 223, middle layer 224 and shift cancelling layer 225, are successively stacked in the z direction from the semiconductor substrate 30 side. The first magnetoresistive effect element 22A is a vertical magnetization-type MTJ element in which the magnetization orientations of the storage layer 221, reference layer 223 and shift cancelling layer 225 are perpendicular to the film plane.

The storage layer 221 is a ferromagnetic layer having a magnetization easy axis direction which is perpendicular to the film plane, and includes, for example, cobalt-iron-boron (CoFeB) or iron boride (FeB). The storage layer 221 has a magnetization orientation toward either the semiconductor substrate 30 side or the reference layer 223 side. The magnetization orientation of the storage layer 221 is set to be reversed more easily than the reference layer 223.

The tunnel barrier layer 222 is a nonmagnetic insulation film, and includes, for example, magnesium oxide (MgO).

The reference layer 223 is a ferromagnetic layer having a magnetization easy axis direction which is perpendicular to the film plane, and includes, for example, cobalt-platinum (CoPt), cobalt-nickel (CoNi) or cobalt-palladium (CoPd). The magnetization orientation of the reference layer 223 is fixed, and is directed toward the shift cancelling layer 225, for example. Incidentally, “magnetization orientation is fixed” means that the magnetization orientation does not change by an electric current with such a magnitude as to be capable of reversing the magnetization orientation of the storage layer 221. A magnetic field is inevitably formed by the reference layer 223, and such a magnetic field is called “stray field”. The stray field may affect a nearby ferromagnetic layer, and may affect, for example, the magnetization orientation of the storage layer 221. For example, the stray field from the reference layer 223 may exert such an influence as to fix the magnetization orientation of the storage layer 221 to be parallel to the magnetization orientation of the reference layer 223. The storage layer 221, tunnel barrier layer 222 and reference layer 223 constitute a magnetic tunnel junction.

The middle layer 224 is a nonmagnetic conductive film, and includes, for example, ruthenium (Ru). The middle layer 224 antiferromagnetically couples the reference layer 223 and shift cancelling layer 225 such that the magnetization orientation of the reference layer 223 and the magnetization orientation of the shift cancelling layer 225 are stabilized in the antiparallel state. Such a coupling structure of the reference layer 223, middle layer 224 and shift cancelling layer 225 is called a SAF (Synthetic Anti-Ferromagnetic) structure.

The shift cancelling layer 225 is a ferromagnetic layer having a magnetization easy axis direction which is perpendicular to the film plane, and includes, for example, cobalt-platinum (CoPt), cobalt-nickel (CoNi) or cobalt-palladium (CoPd). As described above, in the environment in which no magnetic field is applied from the outside, the shift cancelling layer 225 is antiferromagnetically coupled to the reference layer 223 by the middle layer 224. Thus, the magnetization orientation of the shift cancelling layer 225 is fixed to be antiparallel to the magnetization orientation of the reference layer 223, and is oriented toward the reference layer 223 side, for example. The magnitude of the magnetic field, which is necessary for reversing the magnetization orientation of the shift cancelling layer 225, is set at a greater value than the magnitude of the magnetic field that is necessary for reversing the magnetization orientation of the reference layer 223. In addition, the stray field from the shift cancelling layer 225 may affect the magnetization orientation of the storage layer 221. When the magnetization orientation of the shift cancelling layer 225 is antiparallel to the magnetization orientation of the reference layer 223, the stray field from the shift cancelling layer 225 reduces the influence which is exerted by the stray field from the reference layer 223 upon the magnetization orientation of the storage layer 221. It is ideal that the stray field from the shift cancelling layer 225 cancels the stray field from the referenced layer 223. However, the stray fields from the reference layer 223 and shift cancelling layer 225 do not always completely cancel each other. Thus, there exist stray fields from the reference layer 223 and shift cancelling layer 225 in the same memory cell 20. In the description below, such stray fields from the reference layer 223 and shift cancelling layer 225 in the same memory cell 20 are referred to as “synthetic stray field”.

Part (B) of FIG. 3 is a cross-sectional view illustrating a cross section of the second magnetoresistive effect element of the magnetic storage device according to the embodiment, which is cut along a plane perpendicular to the xy plane. As illustrated in part (B) of FIG. 3, like the first magnetoresistive effect element 22A, the second magnetoresistive effect element 22B includes a storage layer 221, a tunnel barrier layer 222, a reference layer 223, a middle layer 224, and a shift cancelling layer 225.

The configuration of the second magnetoresistive effect element 22B is the same as the configuration of the first magnetoresistive effect element 22A, except that each of the magnetization orientation of the reference layer 223 and the magnetization orientation of the shift cancelling layer 225 is opposite to the magnetization orientation in the first magnetoresistive effect element 22A. Specifically, the magnetization orientation of the reference layer 223 of the second magnetoresistive effect element 22B is opposite to the magnetization orientation of the reference layer 223 of the first magnetoresistive effect element 22A. In addition, the magnetization orientation of the shift cancelling layer 225 of the second magnetoresistive effect element 22B is opposite to the magnetization orientation of the shift cancelling layer 225 of the first magnetoresistive effect element 22A.

In the meantime, in the embodiment, a spin transfer torque writing method is adopted in which a write current is caused to directly flow through the first magnetoresistive effect element 22A and second magnetoresistive effect element 22B, and the magnetization orientation of the storage layer 221 is controlled by this write current. The first magnetoresistive effect element 22A and second magnetoresistive effect element 22B can take either a low resistance state or a high resistance state, depending on whether the relative relationship between the magnetization orientations of the storage layer 221 and reference layer 223 is parallel or antiparallel.

If a write current in the direction of an arrow a1 in part (A) of FIG. 3, that is, in a direction from the storage layer 221 toward the reference layer 223, is passed through the first magnetoresistive effect element 22A, the relative relationship between the magnetization orientations of the storage layer 221 and reference layer 223 becomes parallel. In addition, if a write current in the direction of an arrow b1 in part (B) of FIG. 3, that is, in a direction from the storage layer 221 toward the reference layer 223, is passed through the second magnetoresistive effect element 22B, the relative relationship between the magnetization orientations of the storage layer 221 and reference layer 223 becomes parallel. In the case of this parallel state, the resistance values of the first magnetoresistive effect element 22A and second magnetoresistive effect element 22B become lowest, and the first magnetoresistive effect element 22A and second magnetoresistive effect element 22B are set in the low resistance state. This low resistance state is called “P (Parallel) state”, and is defined as a state of data “0”, for instance.

If a write current in the direction of an arrow a2 in part (A) of FIG. 3, that is, in a direction from the reference layer 223 toward the storage layer 221, is passed through the first magnetoresistive effect element 22A, the relative relationship between the magnetization orientations of the storage layer 221 and reference layer 223 becomes antiparallel. In addition, if a write current in the direction of an arrow b2 in part (B) of FIG. 3, that is, in a direction from the reference layer 223 toward the storage layer 221, is passed through the second magnetoresistive effect element 22B, the relative relationship between the magnetization orientations of the storage layer 221 and reference layer 223 becomes antiparallel. In the case of this antiparallel state, the resistance values of the first magnetoresistive effect element 22A and second magnetoresistive effect element 22B become highest, and the first magnetoresistive effect element 22A and second magnetoresistive effect element 22B are set in the high resistance state. This high resistance state is called “AP (Anti-Parallel) state”, and is defined as a state of data “1”, for instance.

These resistance states of the first magnetoresistive effect element 22A and second magnetoresistive effect element 22B are semipermanently retained, but the resistance state may be reversed due to external factors. Here, the difficulty in reversal of the resistance state is called “retention characteristics”. The retention characteristics may deteriorate due to, for example, the influence of a synthetic stray field, or a temperature disturbance.

In the description below, the first magnetoresistive effect element 22A and second magnetoresistive effect element 22B are discriminately described, where necessary. In addition, when the first magnetoresistive effect element 22A and second magnetoresistive effect element 22B are not particularly discriminated, the first magnetoresistive effect element 22A and second magnetoresistive effect element 22B are described simply as “magnetoresistive effect element 22”.

1.1.4. Re: Relationship Between Arrangement and Magnetization Orientations of Magnetoresistive Effect Elements

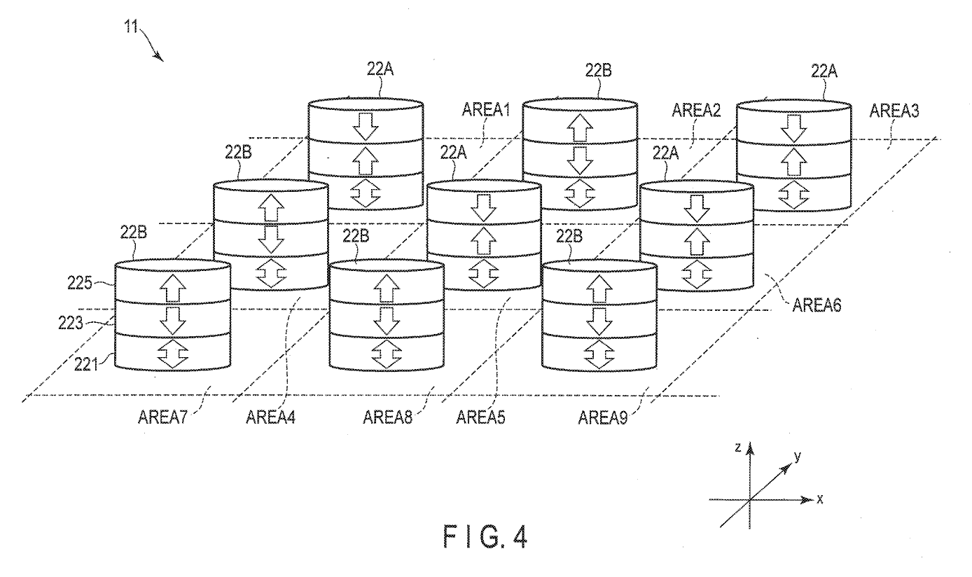

Next, referring to FIG. 4, a description is given of the relationship between the arrangement and magnetization orientations of the magnetoresistive effect elements of the magnetic storage device according to the embodiment. FIG. 4 is a perspective view which schematically illustrates an example of the relationship between the arrangement and magnetization orientations of a plurality of first magnetoresistive effect elements and second magnetoresistive elements which are provided in the memory cell array of the magnetic storage device according to the embodiment. In FIG. 4, structural parts of the first magnetoresistive effect elements 22A and second magnetoresistive effect elements 22B, excluding the storage layers 221, reference layers 223 and shift cancelling layers 225, are omitted for the purpose of simplicity. Similarly, structural parts in the memory cell 20, excluding the first magnetoresistive effect elements 22A and second magnetoresistive effect elements 22B, and structural parts for connecting memory cells 20, are omitted.

As illustrated in FIG. 4, in the memory cell array 11, the area where plural memory cells 20 are provided is divided, for example, with no gap by an arrangement pattern including arrangement areas AREA1 to AREA9. Each of the arrangement areas AREA1 to AREA9 in the arrangement pattern is set for disposing one memory cell 20. Each of the arrangement areas AREA1 to AREA9 is, for example, rectangular, and the arrangement areas AREA1 to AREA9 are distributed in a matrix in the xy plane. Two arrangement areas, which neighbor each other, share one side thereof. Two arrangement areas, which do not neighbor each other, do not share one side thereof. For example, the arrangement area AREA5 neighbors the arrangement areas AREA2, AREA4, AREA6 and AREA8, but does not neighbor the arrangement areas AREA1, AREA3, AREA7 and AREA9.

The memory cells 20 are arranged, one by one, in the arrangement areas AREA1 to AREA9 in this arrangement pattern. Specifically, one memory cell 20 including either the first magnetoresistive effect element 22A or second magnetoresistive effect element 22B is disposed in each of the arrangement areas AREA1 to AREA9. In the meantime, the first magnetoresistive effect element 22A or second magnetoresistive effect element 22B is disposed at random in each of the arrangement areas AREA1 to AREA9. Specifically, a first magnetoresistive effect element 22A is disposed in the arrangement area, independently from the arrangement of the other first magnetoresistive effect elements 22A and second magnetoresistive effect elements 22B. In addition, a second magnetoresistive effect element 22B is disposed in the arrangement area, independently from the arrangement of the other second magnetoresistive effect elements 22B and first magnetoresistive effect elements 22A. The number of first magnetoresistive effect elements 22A and the number of second magnetoresistive effect elements 22B are, for example, substantially equal. The phrase “substantially equal” means that each of the number of first magnetoresistive effect elements 22A and the number of second magnetoresistive effect elements 22B is in the range of (50±1)% of the number of all magnetoresistive effect elements 22 in the magnetic storage device 1. Incidentally, the number of first magnetoresistive effect elements 22A and the number of second magnetoresistive effect elements 22B may be out of the range of “substantially equal”. For example, each of the number of first magnetoresistive effect elements 22A and the number of second magnetoresistive effect elements 22B may be in the range of (50±5)%, (50±10)%, (50±20)%, (50±30)%, (50±40)% or (50±45)% of the number of all magnetoresistive effect elements 22 in the magnetic storage device 1.

In the example of FIG. 4, first magnetoresistive effect elements 22A are disposed in the arrangement areas AREA1, AREA3, AREA5 and AREA6. In addition, second magnetoresistive effect elements 22B are disposed in the arrangement areas AREA2, AREA4, and AREA7 to AREA9.

As described above, respective layers in the magnetoresistive effect element 22, in particular, the reference layer 233 and shift cancelling layer 255, generate a synthetic stray field, and the synthetic stray field may affect the magnetization orientation of another nearby ferromagnetic layer such as the storage layer 221. Thus, a synthetic stray field from a certain arrangement area may affect a synthetic stray field from another arrangement area. In the meantime, the influence, which is exerted on the synthetic stray field of a certain arrangement area by the synthetic stray field from another arrangement area, becomes stronger as the distance between this certain arrangement area and this another arrangement area becomes shorter. Thus, when the certain arrangement area and the another arrangement area neighbor each other, the synthetic stray field from the certain arrangement area is affected from the synthetic stray field from the another arrangement area by a non-negligible degree. On the other hand, when the certain arrangement area and the another arrangement area do not neighbor reach other, the synthetic stray field from the certain arrangement area is affected from the synthetic stray field from the another arrangement area by only a negligible degree.

In the example of FIG. 4, the first magnetoresistive effect element 22A, which is disposed in the arrangement area AREA5, may be affected by the synthetic stray fields from the first magnetoresistive effect element 22A in the arrangement area AREA6, and from the second magnetoresistive effect elements 22B in the arrangement areas AREA2, AREA4 and AREA8. On the other hand, the first magnetoresistive effect element 22A, which is disposed in the arrangement area AREA5, is hardly affected by the synthetic stray fields from the first magnetoresistive effect elements 22A in the arrangement areas AREA1 and AREA3, and from the second magnetoresistive effect elements 22B in the arrangement areas AREA7 and AREA9.

In the description below, that the arrangement areas “neighbor” means that the magnetoresistive effect elements 22 disposed in the arrangement areas are close to each other to such a degree that the magnetoresistive effect elements 22 are affected by each other's synthetic stray field. In addition, that the arrangement areas “do not neighbor” means that the magnetoresistive effect elements 22 disposed in the arrangement areas are spaced apart from each other to such a degree that the influence from each other's synthetic stray field is negligible.

As described above, the retention characteristics may deteriorate by the synthetic stray field, and the synthetic stray field may affect the magnetization orientation of another nearby ferromagnetic layer. Thus, the retention characteristics of the magnetoresistive element 22 in an arrangement area may deteriorate due to the stray field from a neighboring arrangement area. In addition, the influence, which is exerted on the retention characteristics of the magnetoresistive effect element 22 of an arrangement area by the synthetic stray field from a neighboring arrangement area, depends on whether the magnetization orientations of the shift cancelling layers 225 of the magnetoresistive effect elements 22 in the respective arrangement areas are parallel or antiparallel. Specifically, the retention characteristics of the first magnetoresistive effect element 22A in a certain arrangement area may greatly deteriorate by the synthetic stray field of the first magnetoresistive effect element 22A in a neighboring arrangement area. On the other hand, the retention characteristics of the first magnetoresistive effect element 22A in a certain arrangement area do not greatly deteriorate, or hardly deteriorate, by the synthetic stray field of the second magnetoresistive effect element 22B in a neighboring arrangement area. The degree, by which the retention characteristics of the first magnetoresistive effect element 22A in a certain arrangement area deteriorate by the synthetic stray field, is greater, at least, in the case in which the first magnetoresistive effect element 22A exists in the neighboring arrangement area, than in the case in which the second magnetoresistive effect element 22B exists in the neighboring arrangement area.

In the example of FIG. 4, the retention characteristics of the first magnetoresistive effect element 22A disposed in the arrangement area AREA5 greatly deteriorate by the synthetic stray field of the first magnetoresistive effect element 22A in the neighboring arrangement area AREA6. On the other hand, the retention characteristics of the first magnetoresistive effect element 22A disposed in the arrangement area AREA5 do not greatly deteriorate, or hardly deteriorate, by the synthetic stray fields of the second magnetoresistive effect elements 22B in the neighboring arrangement areas AREA2, AREA4 and AREA8.

1.2. Re: Manufacturing Method

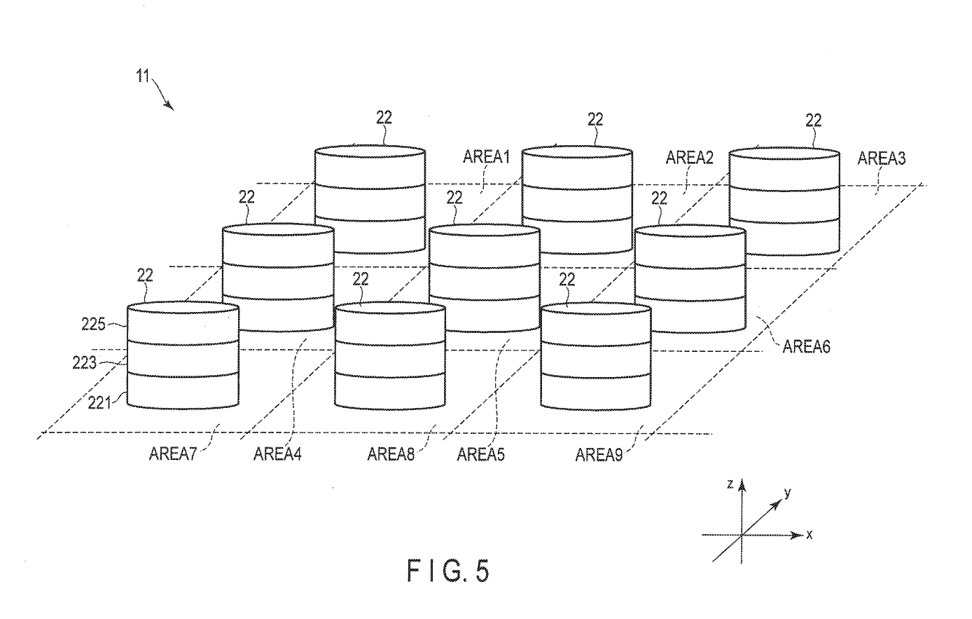

Next, referring to FIG. 5 to FIG. 9, an overall manufacturing method of the magnetic storage device according to the embodiment is described. FIG. 5 to FIG. 9 are perspective views illustrating the memory cell array of the magnetic storage device according to the embodiment, and illustrate a plurality of magnetoresistive effect elements in parts of the manufacturing process.

As illustrated in FIG. 5, a plurality of magnetoresistive effect elements 22 are formed above the semiconductor substrate 30 (not shown). Specifically, for example, a first ferromagnetic film, which is to function as the storage layer 221, is deposited above the semiconductor substrate 30. A first nonmagnetic film, which is to function as the tunnel barrier layer 222, is deposited above the first ferromagnetic film. A second ferromagnetic film, which is to function as the reference layer 223, is deposited above the first nonmagnetic film. A second nonmagnetic film, which is to function as the middle layer 224, is deposited above the second ferromagnetic film. A third ferromagnetic film, which is to function as the shift cancelling layer 225, is deposited above the second nonmagnetic film. The first ferromagnetic film, first nonmagnetic film, second ferromagnetic film, second nonmagnetic film and third ferromagnetic film, excluding the regions thereof where the first magnetoresistive effect elements 22A and second magnetoresistive effect elements 22B are to be provided, are removed by etching. The regions where the first magnetoresistive effect elements 22A and second magnetoresistive effect elements 22B are to be provided are set, for example, based on the arrangement pattern including the arrangement areas AREA1 to AREA9. As a result, a plurality of magnetoresistive effect elements 22, which are to function as the first magnetoresistive effect elements 22A and second magnetoresistive effect elements 22B, are formed, one by one, in the respective arrangement areas AREA1 to AREA9. In the meantime, although the plural magnetoresistive effect elements 22 are formed, for example, by identical fabrication steps, there may be a variance in characteristics due to manufacturing errors. Specifically, for example, among the plural magnetoresistive effect elements 22, there may be a variance, due to manufacturing errors, in the minimum values of the magnetic field by which the magnetization orientation of the shift cancelling layer 225 is reversed. The manufacturing errors do not depend on specific arrangement areas in the arrangement pattern.

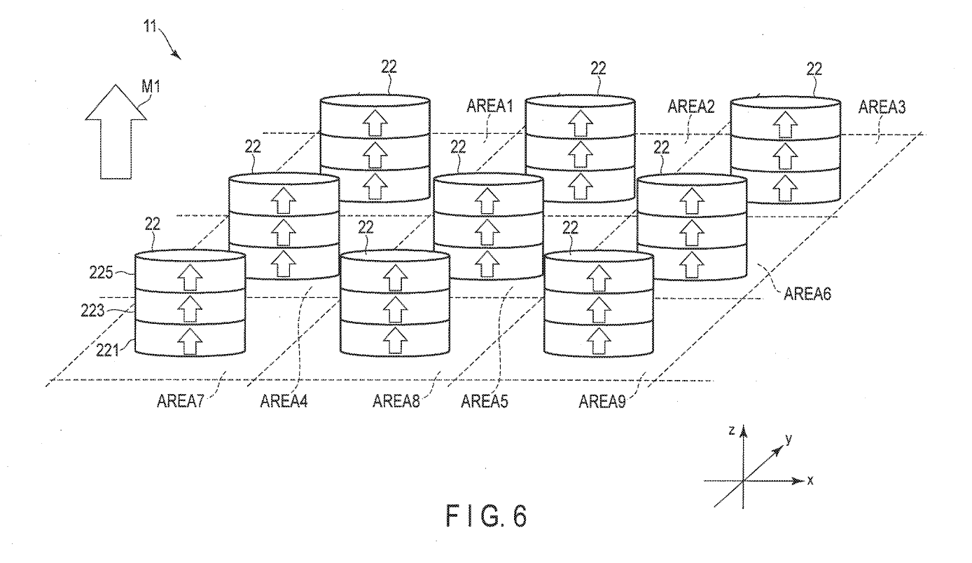

As illustrated in FIG. 6, a first magnetic field is applied to the plural magnetoresistive effect elements 22 in a first direction. In the example of FIG. 6, the first direction is a direction of an arrow M1 shown in FIG. 6, and is an upward z direction. The first magnetic field has such a magnitude as to be capable of reversing the magnetization orientations of all shift cancelling layers 225 of the plural magnetoresistive effect elements 22. Accordingly, all of the storage layer 221, reference layer 223 and shift cancelling layer 225 of each of all magnetoresistive effect elements 22 are magnetized in the magnetization orientation toward the first direction by the first magnetic field.

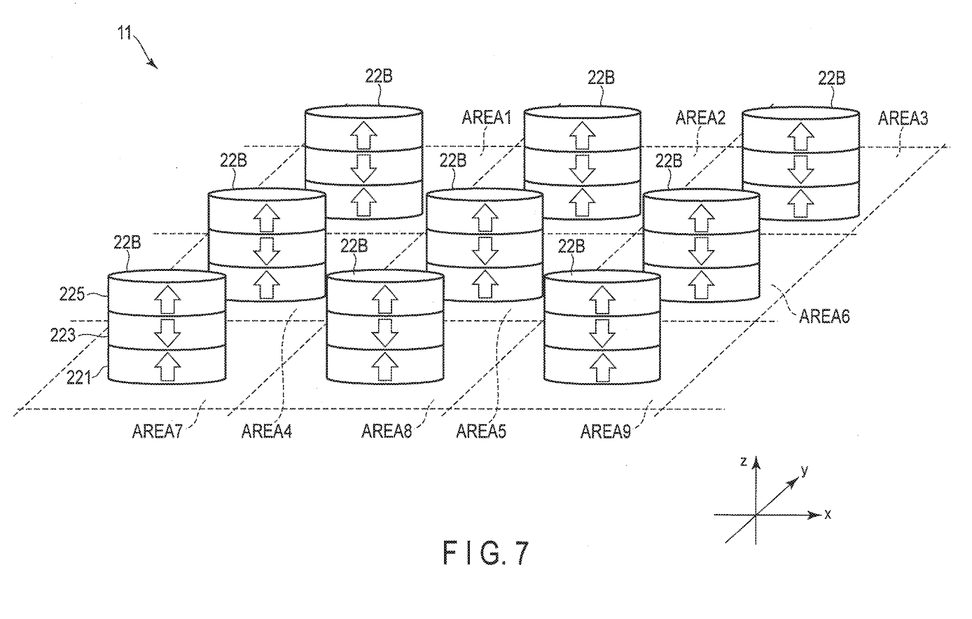

Subsequently, the magnetization by the first magnetic field is finished, and the magnetic field applied from the outside is cut off. Then, as illustrated in FIG. 7, the magnetization orientations of all reference layers 223 of the plural magnetoresistive effect elements 22 are reversed to antiparallel directions to the magnetization orientations of the shift cancelling layers 225 by the effect of antiferromagnetic coupling between the reference layers 223 and the shift cancelling layers 225. In short, all magnetoresistive effect elements 22 are magnetized as second magnetoresistive effect elements 22B. Incidentally, the magnetization orientations of the storage layers 221 of all magnetoresistive effect elements 22 do not change by the cut-off of the magnetic field that is applied from the outside.

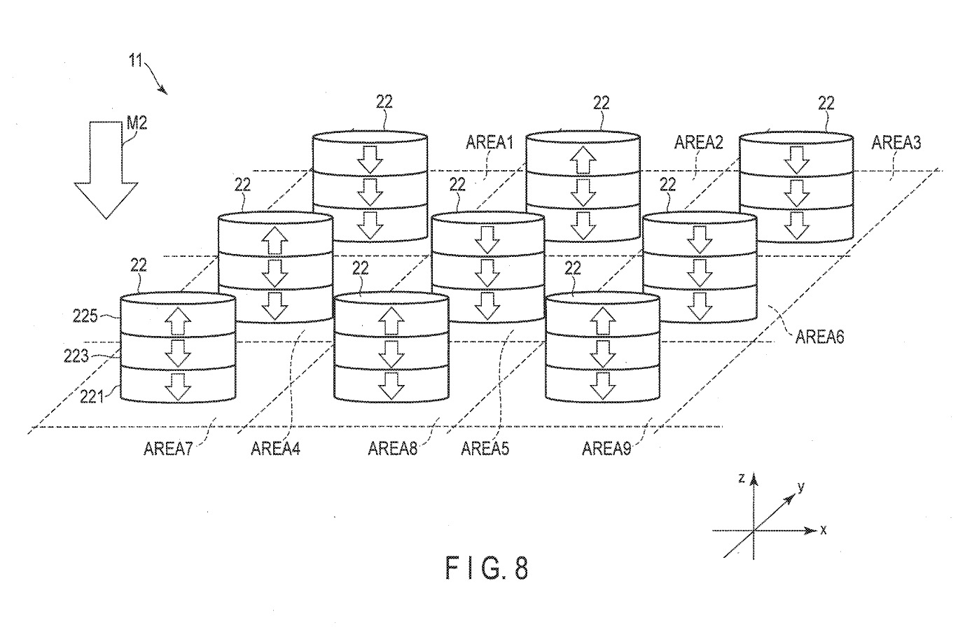

Subsequently, as illustrated in FIG. 8, a second magnetic field is applied to the plural magnetoresistive effect elements 22 in a second direction which is opposite to the first direction. In the example of FIG. 8, the second direction is a direction of an arrow M2 shown in FIG. 8, and is a downward z direction. The second magnetic field has such a magnitude as to be capable of reversing the magnetization orientation of at least one shift cancelling layer 225 of the plural magnetoresistive effect elements 22. In addition, the second magnetic field has no such magnitude as to reverse the magnetization orientations of all shift cancelling layers 225 of the plural magnetoresistive effect elements 22. Accordingly, at least one (not all) of the shift cancelling layers 225 of the plural magnetoresistive effect elements 22 is magnetized in the magnetization orientation toward the second direction by the second magnetic field. In addition, all of the storage layers 221 and reference layers 223 of the plural magnetoresistive effect elements 22 are magnetized in the magnetization orientation toward the second direction by the second magnetic field.

In the meantime, as described above, the minimum values of the magnetic fields, which reverse the magnetization orientations of the shift cancelling layers 225 in the plural magnetoresistive effect elements 22, vary at random in the arrangement pattern. Thus, the magnetoresistive effect elements, in which the shift cancelling layers 225 are magnetized in the magnetization orientation toward the second direction by the second magnetic field, are distributed at random in the arrangement pattern. In the example of FIG. 8, the shift cancelling layers 225 of the magnetoresistive effect elements 22, which are disposed in the arrangement areas AREA1, AREA3, AREA5 and AREA6, are magnetized in the second direction by the second magnetic field. In addition the shift cancelling layers 225 of the magnetoresistive effect elements 22, which are disposed in the arrangement areas AREA2, AREA4, and AREA7 to AREA9, are not magnetized in the second direction by the second magnetic field, and have magnetization orientations in the first direction.

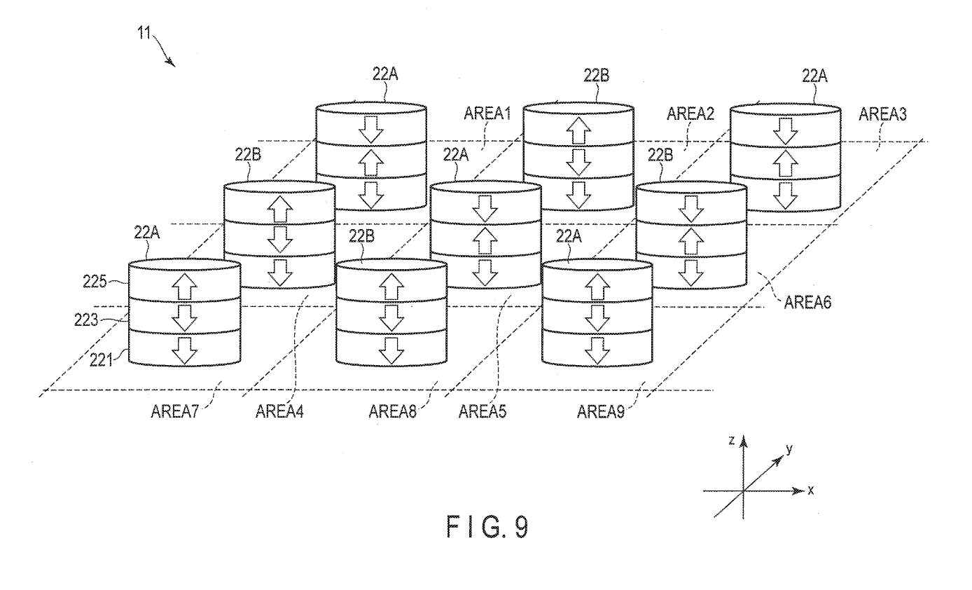

Subsequently, the magnetization by the second magnetic field is finished, and the magnetic field applied from the outside is cut off. Then, as illustrated in FIG. 9, the magnetization orientations of the reference layers 223 of all magnetoresistive effect elements 22 are reversed to antiparallel directions to the magnetization orientations of the shift cancelling layers 225 by the effect of antiferromagnetic coupling between the reference layers 223 and the shift cancelling layers 225. In the example of FIG. 9, the magnetization orientations of the reference layers 223 of the magnetoresistive effect elements 22, which are disposed in the arrangement areas AREA1, AREA3, AREA5 and AREA6, are oriented in the first direction which is antiparallel to the magnetization orientations of the shift cancelling layers 225. In addition, the magnetization orientations of the reference layers 223 of the magnetoresistive effect elements 22, which are disposed in the arrangement areas AREA2, AREA4, and AREA7 to AREA9, do not change from the state illustrated in FIG. 8, and are oriented in the second direction. As a result, first magnetoresistive effect elements 22A are provided in the arrangement areas AREA1, AREA3, AREA5 and AREA6, and second magnetoresistive effect elements 22B are provided in the arrangement areas AREA2, AREA4, and AREA7 to AREA9. In the meantime, after the end of magnetization by the second magnetic field, the magnetization orientations of the storage layer 221 and reference layer 223 of the first magnetoresistive effect element 22A are antiparallel. In addition, the magnetization orientations of the storage layer 221 and reference layer 223 of the second magnetoresistive effect element 22B are parallel. In other words, after the end of magnetization by the second magnetic field, the first magnetoresistive effect elements 22A are in the AP state, and the second magnetoresistive effect elements 22B are in the P state.

Thereafter, returning to normal fabrication steps, the memory cell array 11, etc. are provided on the semiconductor substrate 30, and the magnetic storage device 1 is obtained.

In the meantime, the second magnetic field may be determined during the manufacturing process of the magnetic storage device 1, and the determined second magnetic field may be applied in the manufacturing process of the magnetic storage device 1 or a new magnetic storage device. When the second magnetic field is determined, for example, a magnetic field, which has such a magnitude that about half the plural magnetoresistive effect elements 22 are set in the AP state, is selected.

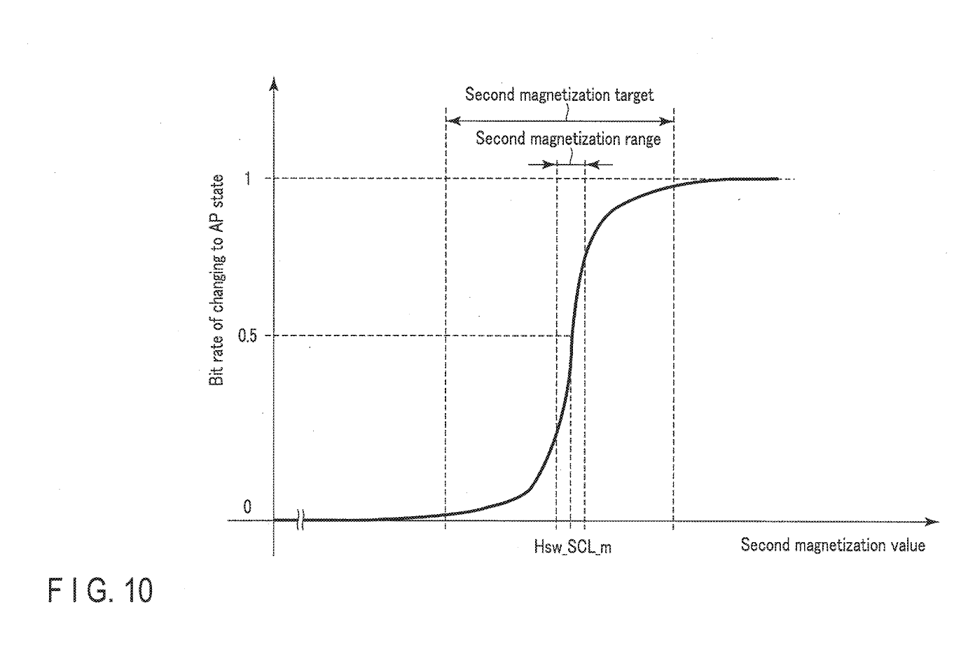

FIG. 10 is a diagram illustrating an example of the characteristics of a plurality of magnetoresistive effect elements of the magnetic storage device according to the embodiment. In the example of FIG. 10, the magnitude of the second magnetic field, which is applied to the plural magnetoresistive effect elements 22, and the ratio of magnetoresistive effect elements 22, which enter the AP state after the application of the second magnetic field, to all the magnetoresistive effect elements 22, are associated and illustrated. Such distribution information is obtained, for example, by passing a read current through each of the plural magnetoresistive effect elements 22 after the end of application of the second magnetic field, and measuring the resistance value thereof.

As described above, due to manufacturing errors, the minimum magnitudes of the magnetic field, at which the magnetization orientation of the shift cancelling layer 225 reverses, vary among the plural magnetoresistive effect elements 22. Thus, the ratio of first magnetoresistive effect elements 22A, to which second magnetoresistive effect elements 22B change after the magnetization by the second magnetic field, gradually increases from 0, as the magnitude of the applied second magnetic field becomes greater. Accordingly, as illustrated in the distribution information of FIG. 10, the ratio of magnetoresistive effect elements in the AP state among the plural magnetoresistive effect elements 22 gradually increases from 0, as the magnitude of the applied second magnetic field becomes greater. For example, if the second magnetic field with a vale Hsw_SCL_m is applied, about half the plural magnetoresistive effect elements 22 enter the AP state. In addition, if the second magnetic field with a value exceeding the vale Hsw_SCL_m is applied, the ratio of magnetoresistive effect elements 22, which change from the P state to AP state (change from second magnetoresistive effect elements 22B to first magnetoresistive effect elements 22A), gradually approaches 1.

In order to reduce the effect of the synthetic stray magnetic field between neighboring magnetoresistive effect elements 22, it is desirable to include at least one first magnetoresistive effect element 22A and at least one second magnetoresistive effect element 22B. Thus, the magnitude of the second magnetic field is selected within such a range that the ratio of magnetoresistive effect elements 22, which change from the P state to PA state, is greater than 0 and is less than 1. To be more specific, the second magnetic field should preferably have such a magnitude that about half the plural magnetoresistive effect elements 22 change from the P state to AP state. In short, it is desirable that a value within a range including the value Hsw_SCL_m be selected for the second magnetic field.

1.3. Advantageous Effect of Present Embodiment

With the advancement in miniaturization of magnetic storage devices in accordance with the enhancement in integration density, the width between magnetoresistive effect elements has been decreasing. If the width between magnetoresistive effect elements decreases, the retention characteristics are affected by the synthetic stray field from the neighboring magnetoresistive effect element.

According to the embodiment, the magnetic storage device 1 includes the first magnetoresistive effect element 22A and second magnetoresistive effect element 22B of the SAF structure. The magnetization orientations of the shift cancelling layers 225 of the first magnetoresistive effect element 22A and second magnetoresistive effect element 22B are antiparallel to each other. Substantially equal numbers of such magnetoresistive effect elements 22A and second magnetoresistive effect elements 22B are arranged at random in the arrangement pattern including the plural arrangement areas AREA1 to AREA9. Thereby, it is possible to reduce such an influence that the retention characteristics of a magnetoresistive effect element 22 deteriorate due to a synthetic stray field from another neighboring magnetoresistive effect element 22.

If a supplementary description is given, the first magnetoresistive effect element 22A and second magnetoresistive effect element 22B, which are disposed in mutually neighboring arrangement areas, reduce the influence of the synthetic stray field upon each other's storage layer 221. In order to more efficiently reduce the influence of the synthetic stray field, it is desirable that all magnetoresistive effect elements 22, which neighbor the first magnetoresistive effect element 22A, be always the second magnetoresistive effect element 22B. However, it is very difficult to regularly arrange the first magnetoresistive effect elements 22A and second magnetoresistive effect elements 22B such that the first magnetoresistive effect element 22A and second magnetoresistive effect element 22B always neighbor each other.

In the magnetic storage device 1 according to the embodiment, the first magnetoresistive effect elements 22A and second magnetoresistive effect elements 22B are arranged at random in the arrangement pattern. In this case, the magnetic storage device 1 includes at least one pair of mutually neighboring first magnetoresistive effect element 22A and second magnetoresistive effect element 22B. In addition, the magnetic storage device 1 may include at least one pair of mutually neighboring first magnetoresistive effect element 22A and first magnetoresistive effect element 22A. The magnetic storage device 1 may also include at least one pair of mutually neighboring second magnetoresistive effect element 22B and second magnetoresistive effect element 22B.

In addition, the magnetic storage device 1 according to the embodiment includes substantially equal numbers of first magnetoresistive effect elements 22A and second magnetoresistive effect elements 22B. In this case, an expected value of the number of pairs of mutually neighboring first magnetoresistive effect elements 22A and second magnetoresistive effect elements 22B becomes a maximum. It is thus possible to effectively reduce the effect of the synthetic stray fields between the first magnetoresistive effect elements 22A and second magnetoresistive effect elements 22B. Therefore, it is possible to reduce the deterioration of the retention characteristics of the magnetic storage device 1 due to the effect of the synthetic stray field from the neighboring magnetoresistive effect element 22.

In addition, according to the embodiment, the magnetic storage device 1 is manufactured by applying the first magnetic field in the first direction, and thereafter applying the second magnetic field, which is less than the first magnetic field, in the second direction which is opposite to the first direction. The first magnetic field has such a magnitude as to reverse the magnetization orientations of the shift cancelling layers 225 of all magnetoresistive effect elements 22 in the magnetic storage device 1. The second magnetic field has such a magnitude as to reverse the magnetization orientations of the shift cancelling layers 225 of about half the magnetoresistive effect elements 22 in the magnetic storage device 1. Thus, the magnetic storage device 1, which includes substantially equal numbers of first magnetoresistive effect elements 22A and second magnetoresistive effect elements 22B, can be manufactured by a small number of magnetization steps, i.e. two magnetic initialization steps. In addition, the magnitudes of magnetic fields, at which the magnetization orientations of the shift cancelling layers 225 in the plural magnetoresistive effect elements 22 formed in the magnetic storage device 1 are reversed, are distributed at random in the arrangement pattern. Thus, the first magnetoresistive effect elements 22A and second magnetoresistive effect elements 22B are arranged at random in the arrangement pattern of the magnetic storage device 1. Thereby, it is possible to increase the probability that the first magnetoresistive effect elements 22A and second magnetoresistive effect elements 22B neighbor each other in the magnetic storage device 1. Therefore, it is possible to reduce the deterioration of the retention characteristics of the magnetic storage device 1 due to the effect of the synthetic stray field from the neighboring magnetoresistive effect element 22.

If a supplementary description is given, due to manufacturing errors, the minimum magnitudes of magnetic fields, at which the magnetization orientations of the shift cancelling layers 225 are reversed, vary among the plural magnetoresistive effect elements 22 formed in the magnetic storage device 1. The second magnetic field is determined on the basis of the distribution information based on such variance. The distribution information is, for example, information in which the magnetic field of an magnitude, which is applied to the plural magnetoresistive effect elements 22, and the ratio of magnetoresistive effect elements 22, in which the magnetization orientations of the shift cancelling layers 225 are reversed by the application of the magnetic field of the magnitude, to all the magnetoresistive effect elements 22, are associated. Based on this distribution information, the magnetic field of a magnitude corresponding to the range, in which the ratio of reversal of shift cancelling layers 225 is greater than 0 and is less than 1, is determined as the second magnetic field. Thereby, it is possible to statistically ensure that the magnetic storage device 1, which includes both the first magnetoresistive effect elements 22A and second magnetoresistive effect elements 22B, is fabricated by the application of the second magnetic field.

In addition, when the first magnetoresistive effect elements 22A and second magnetoresistive effect elements 22B are arranged at random in the arrangement pattern, the number of mutually neighboring first magnetoresistive effect elements 22A and second magnetoresistive effect elements 22B becomes greatest when the number of first magnetoresistive effect elements 22A is equal to the number of second magnetoresistive effect elements 22B. Thus, the second magnetic field is determined from the range including magnitudes of the magnetic field at which the magnetization orientations of about half of all shift cancelling layers 225 are reversed. Thereby, the magnetic storage device 1 including the first magnetoresistive effect elements 22A and second magnetoresistive effect elements 22B, the numbers of which are about half and half, can be manufactured. Specifically, it is possible to increase the probability that the first magnetoresistive effect elements 22A and second magnetoresistive effect elements 22B neighbor each other. Therefore, it is possible to effectively reduce the deterioration of the retention characteristics of the magnetic storage device 1 due to the effect of the synthetic stray field from the neighboring magnetoresistive effect element 22.

1.4. Evaluation Method of Effects of Present Embodiment

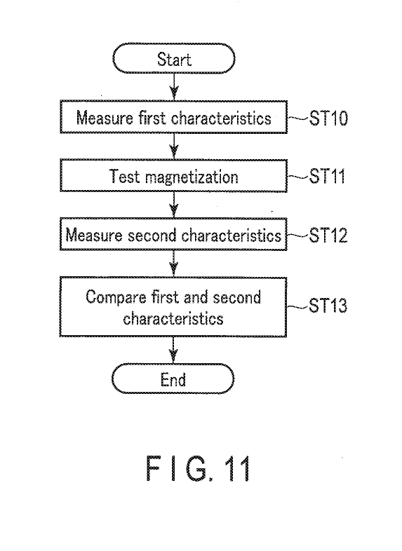

Next, referring to FIG. 11, a description is given of a method of evaluating effects which are obtained by the magnetic storage device 1 according to the embodiment. FIG. 11 is a flowchart illustrating a method of evaluating the effects which are obtained by the magnetic storage device 1 according to the embodiment. Incidentally, the evaluation method illustrated in FIG. 11 is applied to, for example, the magnetic storage device including the magnetoresistive effect element 22 including the SAF structure. In the description below, the magnetic storage device, to which the evaluation method is applied, is referred to as “evaluation target”. It is assumed that all magnetoresistive effect elements 22 in the evaluation target store, for example, identical data. In the meantime, the identical data, which is stored in the plural magnetoresistive effect elements 22, may be “1” or “0”.

As illustrated in FIG. 11, in step ST10, first retention characteristics of the evaluation target are acquired. The first retention characteristics are, for example, information in which an elapsed time and a cumulative error rate are associated with respect to data stored in a plurality of magnetoresistive effect elements 22 in the evaluation target. As means for acquiring the first retention characteristics, for example, such means can be thought that the evaluation target is left in a high-temperature environment for a long time, and the number of reversed data, among the stored data, is measured at every predetermined elapsed time. As the high-temperature environment which is set when the first retention characteristics are acquired, temperatures (e.g. 85° C. or above), at which the magnetization orientation of the storage layer 221 may be reversed by a temperature disturbance, are preferable.

In step ST11, a test magnetic field is applied to the evaluation target, of which the first retention characteristics were acquired, by a magnetization device (not shown). The test magnetic field is, for example, a magnetic field of such a magnitude that the magnetization orientations of all shift cancelling layers 225 are reversed. Thereby, the magnetization orientations of all of the shift cancelling layers 225, reference layers 223 and storage layers 221 in the evaluation target are oriented in the identical direction. Thereafter, if the test magnetic field is cut off, the magnetization orientations of all reference layers 223 in the evaluation target become antiparallel to the magnetization orientations of the shift channeling layers 225. Accordingly, all magnetoresistive effect elements 22 in the evaluation target enter the AP state (data “1” is stored).

Subsequently, in step ST12, second retention characteristics of the evaluation target are acquired. The second retention characteristics are acquired by the same step as the acquisition of the first retention characteristics in step ST10.

In step ST13, the first retention characteristics and second retention characteristics are compared. As a result of the comparison, if the second retention characteristics become worse than the first retention characteristics, it is determined that the evaluation target includes at least one pair of mutually neighboring first magnetoresistive effect element 22A and second magnetoresistive effect element 22B. On the other hand, if the second retention characteristics remain the same as the first retention characteristics, it is determined that the evaluation target includes only either first magnetoresistive effect elements 22A or second magnetoresistive effect elements 22B.

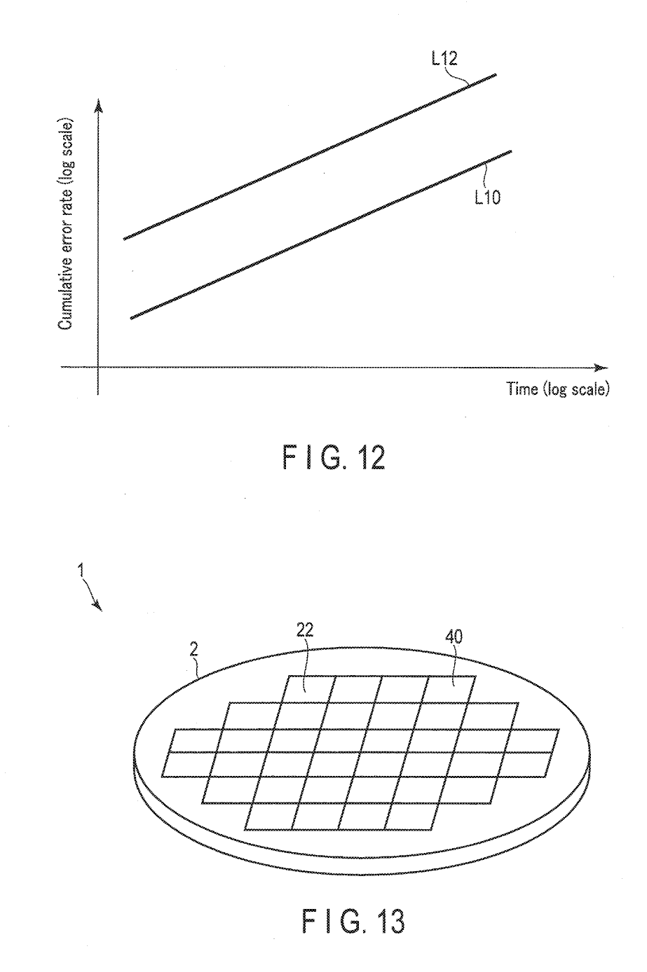

FIG. 12 is a diagram illustrating an example of the evaluation result of the advantageous effects which are obtained by the magnetic storage device 1 according to the embodiment. Incidentally, FIG. 12 illustrates the example of the evaluation result in the case where the evaluation target was the magnetic storage device 1 according to the embodiment.

As illustrated in FIG. 12, the evaluation result is a double-logarithmic graph, and includes first retention characteristics L10 and second retention characteristics L12, which were acquired with respect to the evaluation target. The first retention characteristics L10 and second retention characteristics L12 indicate such characteristics that the cumulative error rate increases with the passing of the time of exposure in the high-temperature environment.

When the evaluation target is the magnetic storage device 1 according to the embodiment, the first retention characteristics L10 are acquired in the state in which the pair of mutually neighboring first magnetoresistive effect element 22A and second magnetoresistive effect element 22B is included. Specifically, the first retention characteristics L10 are retention characteristics which were acquired with respect to the data including data stored in the storage layer 221, the influence upon which by the synthetic stray field from the neighboring magnetoresistive effect element 22 was reduced.

On the other hand, the second retention characteristics L12 are characteristics acquired in the state in which all magnetoresistive effect elements were magnetized as either the first magnetoresistive effect elements 22A or the second magnetoresistive effect elements 22B in step ST11. Thus, the evaluation target does not include the storage layer 221, the influence upon which by the synthetic stray field from the neighboring magnetoresistive effect element 22 was reduced after step ST11. Accordingly, if the first retention characteristics L10 and second retention characteristics L12 are compared, such a tendency is exhibited that the cumulative error rate is lower in the first retention characteristics L10 than in the second retention characteristics L12.

In this manner, by comparing the first retention characteristics L10 and second retention characteristics L12 with respect to the evaluation target, it is possible to determine whether the evaluation target is the magnetic storage device 1 according to the embodiment or not.

### 2. Modifications, Etc.

The embodiments are not limited to the above-described embodiment, and various modifications are possible. Some modifications will be described below.

2.1. First Modification

A magnetic storage device according to a first modification of the embodiment includes a plurality of test patterns in a plurality of magnetoresistive effect elements, and the magnitude of the second magnetic field is determined based on the plural test patterns.

FIG. 13 is a schematic view illustrating a configuration example of the magnetic storage device according to the first modification of the embodiment. The magnetic storage device 1 includes, for example, a wafer 2 for products. In the wafer 2 for products, chips are provided. A chip includes, for example, a plurality of magnetoresistive effect elements 22. A chip includes, for example, a plurality of test patterns 40. The configuration of each of the test patterns 40 includes the same functional configuration as the magnetoresistive effect element 22. In addition, for example, the test pattern further includes a configuration which enables DC (Direct Current) measurement, in order to acquire magnetoresistance value characteristics (hereinafter referred to as “RH characteristics”). In the test pattern 40 with this configuration, the minimum magnitude of the magnetic field, at which the magnetization orientation of the shift cancelling layer 225 is reversed, is substantially equal to the value in the magnetoresistive effect element 22. Thus, based on the RH characteristics measured in the test pattern 40, the magnitude of the magnetic field, which is set for the magnetization of the magnetoresistive effect element 22, can be determined.

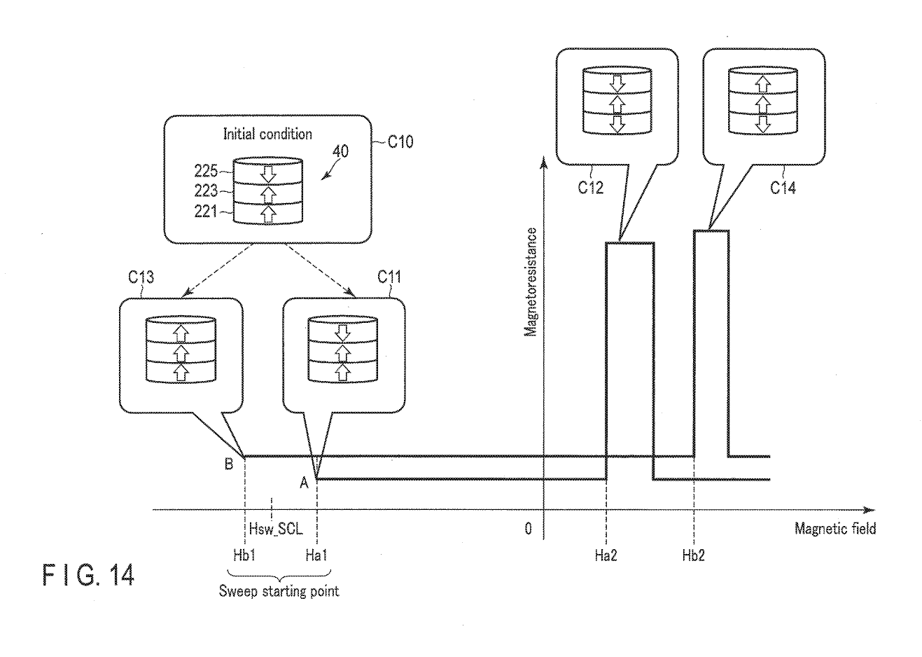

FIG. 14 is a diagram illustrating an example of the RH characteristics of the magnetoresistive effect element of the magnetic storage device according to the first modification of the embodiment. FIG. 14 shows RH characteristics at a time when magnetic fields are applied to a test pattern with two kinds of sweep patterns.

As illustrated in FIG. 14, in an initial state C10, the magnetization orientation of the storage layer 221 of the test pattern 40 is oriented in a direction toward the reference layer 223 side. In addition, the magnetization orientation of the reference layer 223 of the test pattern 40 is oriented in a direction parallel to the magnetization orientation of the storage layer 221. The magnetization orientation of the shift cancelling layer 225 of the test pattern 40 is oriented in a direction antiparallel to the reference layer 223. In the meantime, the magnetization orientation of the shift cancelling layer 225 of the test pattern 40 has such a characteristic that this magnetization orientation is not reversed even if a magnetic field of less than a value Hsw_SCL is applied, and is reversed by the application of the magnetic field of the value Hsw_SCL. The magnetic fields are applied to this test pattern 40 with a first sweep pattern and a second sweep pattern. In the first sweep pattern and second sweep pattern, the magnetic field is swept from a direction, which is antiparallel to the magnetization orientation of the shift cancelling layer 225 in the initial state C10, to a direction which parallel to the magnetization orientation of the shift cancelling layer 225 in the initial state C10.

In the first sweep pattern, sweep is started from a sweep starting time point A. At the sweep start time point A, the magnitude of the magnetic field, which is applied to the test pattern 40, is a value Ha1. The Ha1 is less than the value Hsw_SCL. Thus, as illustrated as a state C11, the magnetization orientation of the shift cancelling layer 225 at the sweep start time point A does not change from the initial state C10. Subsequently, as illustrated in state C12, if the direction of the magnetic field that is swept is reversed and the magnitude of the magnetic field reaches a value Ha2, the magnetization orientation of the storage layer 221 is reversed. Thereby, the magnetization orientation of the storage layer 221 and the magnetization orientation of the reference layer 223 become antiparallel, and the resistance value increases.

On the other hand, in the second sweep pattern, sweep is started from a sweep starting time point B. At the sweep start time point B, the magnitude of the magnetic field, which is applied to the test pattern 40, is a value Hb1. The Hb1 is greater than the value Hsw_SCL. Thus, as illustrated as a state C13, the magnetization orientation of the shift cancelling layer 225 at the sweep start time point B is reversed from the initial state C10. Accordingly, the magnetization orientation of the storage layer 221 in the state C13 is affected by the synthetic stray field from the reference layer 223 and shift cancelling layer 225, and is fixed in the direction of the reference layer 223. Subsequently, even if the direction of the magnetic field that is swept is reversed and the magnitude of the magnetic field reaches the value Ha2, the magnetization orientation of the storage layer 221 is not reversed. The reason for this is that, at the sweep starting time point B, the magnetization orientation of the storage layer 221 was fixed to be the direction parallel to the magnetization orientations of the reference layer 223 and shift cancelling layer 225. Then, as illustrated in state C14, if the magnetic field is further applied from the value Ha2 and the magnitude of the magnetic field reaches a value Hb2, the magnetization orientation of the storage layer 221 is reversed. Thereby, the magnetization orientation of the storage layer 221 and the magnetization orientation of the reference layer 223 become antiparallel, and the resistance value increases.

In this manner, in each of the test patterns 40, the RH characteristics vary depending on whether the magnitude of the magnetic field, which is applied at the sweep starting time point, is greater than the minimum magnetic field which reverses the magnetization orientation of the shift cancel layer 225. Specifically, the ratio of test patterns 40 with the RH characteristics varied by the sweep pattern, in which the magnetic field of a certain magnitude is applied at the sweep starting time point, corresponds to the ratio of those in which the magnetization orientation of the shift cancelling layer 225 is reversed by the magnetic field of the certain magnitude.

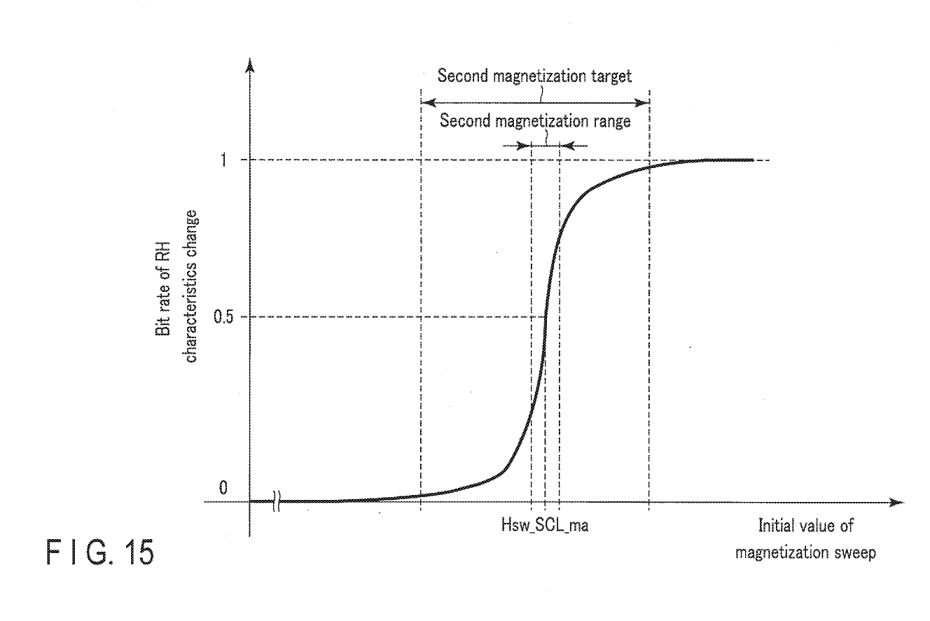

FIG. 15 is a diagram illustrating an example of the characteristics of a plurality of test patterns of the magnetic storage device according to the first modification of the embodiment. In the example of FIG. 15, the magnitudes of magnetic fields at the sweep starting time points in the sweep patterns, which are applied to the plural test patterns 40, and the ratio of test patterns 40, in which the RH characteristics were varied by the sweep patterns, to all test patterns 40, are associated. Such distribution information is acquired, for example, by applying sweep patterns, which start from various sweep starting time points, to a plurality of test patterns 40, and evaluating RH characteristics of each sweep pattern.

In the test patterns 40, like the magnetoresistive effect elements 22, the minimum magnitudes of magnetic fields, at which reversal occurs in the shift cancelling layers 225, vary due to manufacturing errors. Thus, as illustrated in the distribution information of FIG. 15, the ratio of test patterns 40, among the plural test patterns 40, in which the RH characteristics vary, gradually increases from 0, as the magnitude of the magnetic field at the sweep starting time point becomes greater. For example, if the magnetic field having a value Hsw_SCL_ma as the magnitude at the sweep starting time point is applied, the RH characteristics of about half the plural test patterns 40 vary. In addition, if the magnetic field having a value greater than the value Hsw_SCL_ma as the magnitude at the sweep starting time point is applied, the ratio of test patterns 40, in which the RH characteristics vary, gradually approaches 1.

Based on this distribution information, the value of the second magnetic field is selected from the magnitudes of the magnetic fields at the sweep starting time points in the sweep patterns in the case where the ratio of test patterns 40, in which the RH characteristics vary, becomes greater than 0 and less than 1. To be more specific, the second magnetic field should desirably have a magnitude at the sweep starting time point in the sweep pattern in which the RH characteristics of almost half the plural test patterns 40 vary. In other words, it is desirable that a value in the range including the value Hsw_SCL_ma be selected for the second magnetic field.

According to the first modification of the embodiment, the magnetic storage device 1 further includes a plurality of test patterns 40. A plurality of sweep patterns with different magnitudes of magnetic fields at sweep starting time points are applied to the plural test patterns 40, and a plurality of RH characteristics corresponding to the plural test patterns 40 are acquired. Based on the acquired RH characteristics, distribution information is acquired in connection with the magnitudes of magnetic fields at the sweep stating time points and the ratio at which the RH characteristics of the test patterns 40 vary due to the magnitudes of magnetic fields at the sweep stating time points. Based on the acquired distribution information, the magnitude of the magnetic field at the sweep starting time point, with which the RH characteristics of about half the plural test patterns 40 vary, is selected. The selected magnitude of the magnetic field at the sweep starting time point is applied to the magnitude of the second magnetic field. Thereby, the second magnetic field can be determined based on the distribution information acquired from the plural test patterns 40.

2.2. Second Modification

A magnetic storage device according to a second modification of the embodiment includes, for example, a plurality of new magnetoresistive effect elements, and the magnitude of the second magnetic field is determined based on the new magnetoresistive effect elements.

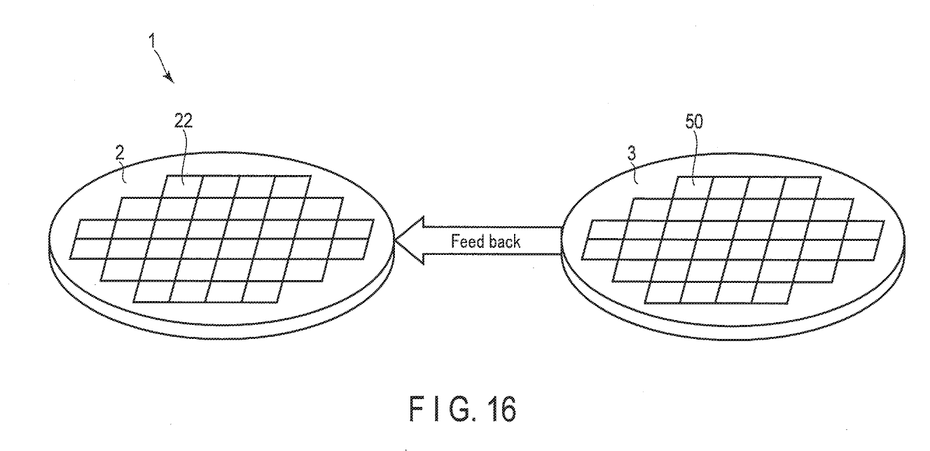

FIG. 16 is a schematic view illustrating a configuration example of the magnetic storage device according to the second modification of the embodiment. The magnetic storage device 1 includes, for example, a wafer 3 for evaluation, in addition to the wafer 2 for products according to the first modification. In the wafer 3 for evaluation, chips are provided. A chip includes, for example, a plurality of new magnetoresistive effect elements 50. Various tests are conducted on the wafer 3 for evaluation, and the result of the conducted tests can be fed back to the wafer 2 for products.

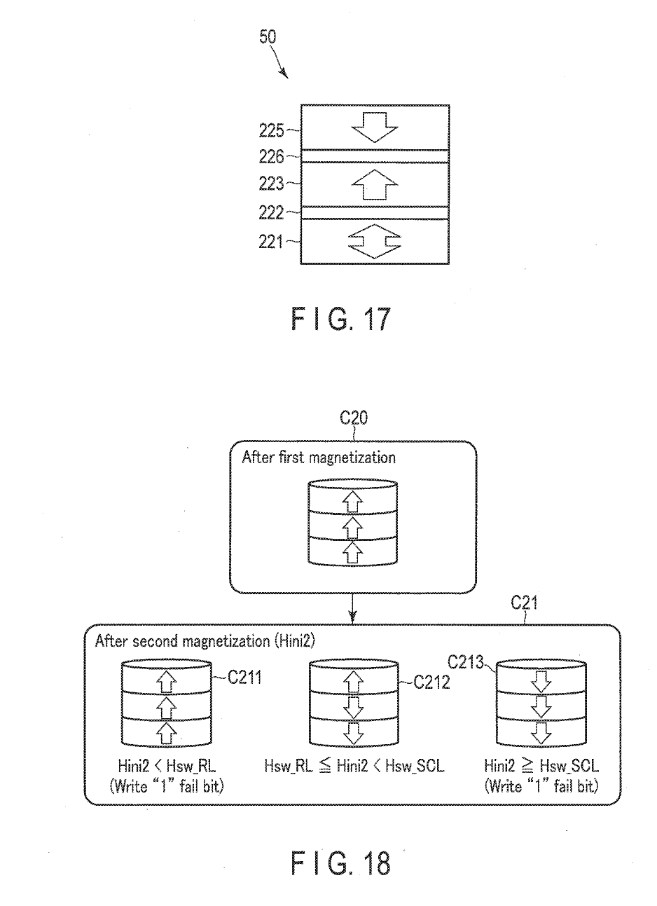

FIG. 17 is a cross-sectional view illustrating a cross section of a new magnetoresistive effect element according to the second modification of the embodiment, the cross section being cut along a plane perpendicular to the xy plane. A new magnetoresistive effect element 50 is provided, for example, on a wafer for evaluation (not shown), and includes a storage layer 221, a tunnel barrier layer 222, a reference layer 223, a middle layer 226 functioning as a fourth nonmagnetic layer, and a shift cancelling layer 225. The functional configurations of the storage layer 221, tunnel barrier layer 222, reference layer 223 and shift cancelling layer 225 are the same as in the embodiment, so a description thereof is omitted.

The middle layer 226 is a nonmagnetic conductive film, and includes, for example, ruthenium (Ru). The middle layer 226 is, for example, thicker than the middle layer 224 or thinner than the middle layer 224. In addition, the middle layer 226 has a weaker coupling force for antiferromagnetically coupling the reference layer 223 and shift cancelling layer 225, than the middle layer 224. In other words, the middle layer 226 does not antiferromagnetically couple the reference layer 223 and shift cancelling layer 225. Specifically, after the magnetization orientations of the reference layer 223 and shift cancelling layer 225 are made parallel by an external magnetic field, the middle layer 226 does not reverse the magnetization orientation of the reference layer 223 to be antiparallel to the magnetization orientation of the shift cancelling layer 225. In this case, even after the external magnetic field is cut off, the magnetization orientation of the reference layer 223 and the magnetization orientation of the shift cancelling layer 225 remain parallel. In short, the new magnetoresistive effect element 50 is not the SAF structure. In the new magnetoresistive effect element 50 with this structure, the minimum magnitude of the magnetic field, at which the magnetization orientation of the shift cancelling layer 225 reverses, is substantially equal to the value in the magnetoresistive effect element 22.

FIG. 18 is a schematic view illustrating an example of the characteristics of the new magnetoresistive effect element of the magnetic storage device according to the second modification of the embodiment. FIG. 18 illustrates the magnetization orientations of the storage layer 221, reference layer 223 and shift cancelling layer 225 at times when a first magnetic field and a second magnetic field were applied to the new magnetoresistive effect element 50.

In a state C20, for example, the first magnetic field is applied to the new magnetoresistive effect element 50, and the storage layer 221, reference layer 223 and shift cancelling layer 225 are magnetized in the same direction. As described above, the new magnetoresistive effect element 50 is not the SAF structure. Thus, in the new magnetoresistive effect element 50, even in the state in which the external magnetic field is cut off after the application of the first magnetic field, the magnetization orientation of the reference layer 223 and the magnetization orientation of the shift cancelling layer 225 are kept in the parallel state.

Subsequently, in a state C21, for example, the second magnetic field is applied to the new magnetoresistive effect element 50 in a direction opposite to the direction of the first magnetic field. The second magnetic field, which has, for example, a value Hini2, is applied. After the application of the second magnetic field, the new magnetoresistive effect element 50 transitions to three states C211 to C213 in accordance with the magnitude of the value Hini2 of the second magnetic field. Specifically, as illustrated in state C211, when the value Hini2 of the second magnetic field is less than a minimum value Hsw_RL at which the magnetization orientation of the reference layer 223 is reversed, the magnetization orientation of the new magnetoresistive effect element 50 does not change. In addition, as illustrated in a state C212, when the value Hini2 of the second magnetic field is the value Hsw_RL or more, and is less than a value Hsw_SCL, the magnetization orientations of the reference layer 223 and storage layer 221 are reversed in the new magnetoresistive element 50. Further, as illustrated in a state C213, when the value Hini2 of the second magnetic field is the Hsw_SCL or more, the magnetization orientations of all of the storage layer 221, reference layer 223 and shift cancelling layer 225 are reversed in the new magnetoresistive element 50. Of these three states C211 to C213, the states C211 and C213 are states in which write of data “1” fails, since the magnetization orientation of the storage layer 211 is fixed by the magnetic fields from the reference layer 223 and shift cancelling layer 225 with parallel magnetization orientations, which do not cancel each other. On the other hand, the state C212 is a state in which data “1” is successfully written.

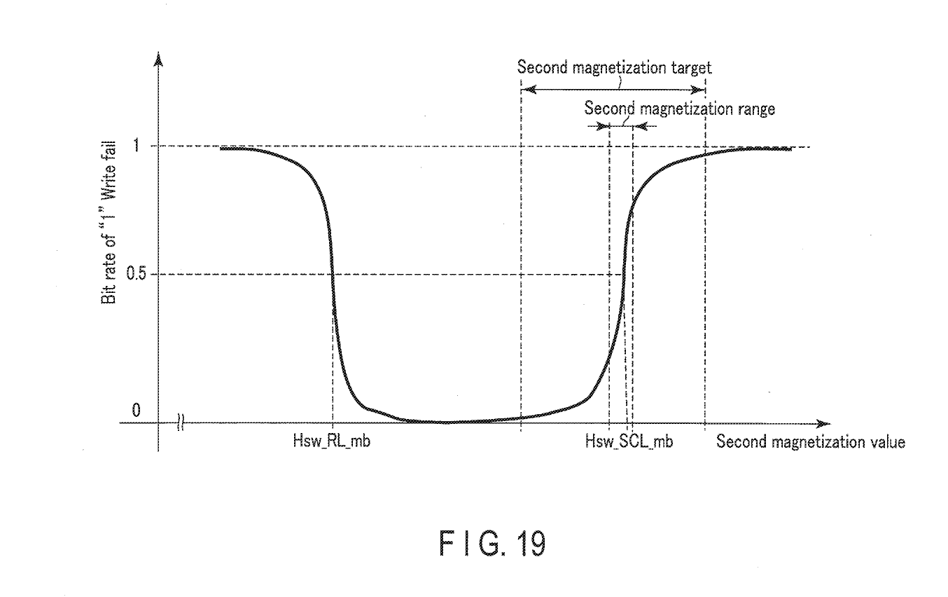

FIG. 19 is a diagram illustrating an example of the characteristics of a plurality of new magnetoresistive effect elements of the magnetic storage device 1 according to the second modification of the embodiment. In the example of FIG. 19, the magnitude of the second magnetic field, and the ratio of new magnetoresistive effect elements 50, in which write of data “1” fails after the application of the second magnetic field, are associated and illustrated. Such distribution information is obtained, for example, by executing data “1” write to each of the new magnetoresistive effect elements 50 to which the second magnetic field was applied, and evaluating the ratio of failures of data “1” write as the result of write, in accordance with the magnitude of the second magnetic field.

In the new magnetoresistive effect elements 50, like the magnetoresistive effect elements 22, the minimum magnitudes of magnetic fields, at which reversal occurs in the reference layers 223, vary due to manufacturing errors. Thus, as illustrated in FIG. 19, the ratio of new magnetoresistive effect elements 50, among the plural new magnetoresistive effect elements 50, in which data “1” write fails, gradually decreases from 1, as the magnitude of the second magnetic field becomes greater. For example, if the magnetic field having a value Hsw_RL_mb is applied as the second magnetic field, data “1” is successfully written in about half the plural new magnetoresistive effect elements 50. In addition, if the magnetic field having a value greater than the value Hsw_RL_mb is applied as the second magnetic field, the ratio of new magnetoresistive effect elements 50, in which data “1” write fails, gradually approaches 0. Furthermore, in the new magnetoresistive effect elements 50, like the magnetoresistive effect elements 22, the minimum magnitudes of magnetic fields, at which reversal occurs in the shift cancelling layers 225, vary due to manufacturing errors. Thus, thereafter, if the magnetic field having a still greater value is applied as the second magnetic field, the ratio of new magnetoresistive effect elements 50, in which data “1” write fails, gradually increases from 0 once again. If the magnetic field having a value Hsw_SCL_mb is applied as the second magnetic field, data “1” write fails in about half the plural new magnetoresistive effect elements 50. If the magnetic field having a still greater value than the value Hsw_SCL_mb is applied as the second magnetic field, the ratio of new magnetoresistive effect elements 50, in which data “1” write fails, gradually approaches 1.

Based on this distribution information, the second magnetic field, which is applied to the magnetic storage device 1, is selected from the range in which the ratio of failures of data “1” write is greater than 0 and less than 1, in the case in which the ratio of failures of data “1” write increases in accordance with the increase in magnitude of the magnetic field. To be more specific, the second magnetic field, which is applied to the magnetic storage device 1, should desirably have a magnitude at which data “1” write fails in almost half the plural new magnetoresistive effect elements 50. In other words, it is desirable that a value in the range including the value Hsw_SCL_mb be selected for the second magnetic field that is applied to the magnetic storage device 1.

According to the second modification of the embodiment, the magnetic storage device 1 further includes a plurality of new magnetoresistive effect elements 50. After the first magnetic field is applied to the plural new magnetoresistive effect elements 50, the second magnetic field is further applied thereto. Then, data “1” write is executed to the plural new magnetoresistive effect elements 50, and the distribution information of the success ratio of data “1” write corresponding to the magnitude of the second magnetic field, which was applied to the plural new magnetoresistive effect elements 50, is acquired. Based on the acquired distribution information, the magnitude of the magnetic field, at which data “1” write fails in almost half the plural new magnetoresistive effect elements 50, is selected. The selected magnitude of the magnetic field is determined to be the magnitude of the second magnetic field which is applied to the magnetic storage device 1. Thereby, the second magnetic field, which is applied to the magnetic storage device 1, can be determined based on the distribution information acquired from the plural new magnetoresistive effect elements 50.

2.3. Other Modifications

In each of the above-described embodiment and modifications, the case was described in which the magnetoresistive effect element 22, the test pattern 40 and the new magnetoresistive effect element 50 are vertical magnetization MTJs. However, the embodiment and modifications are not limited to this case, and these may be horizontal magnetization MTJs having a horizontal magnetic anisotropy.

In addition, in each of the above-described embodiment and modifications, the case was described in which the magnetoresistive effect element 22, the test pattern 40 and the new magnetoresistive effect element 50 are of the bottom free type in which the storage layer 221 is provided on the semiconductor substrate 30 side. However, these may be of a top free type in which the reference layer 223 is provided on the semiconductor substrate 30 side.

While certain embodiments have been described, these embodiments have been presented by way of example only, and are not intended to limit the scope of the inventions.

Indeed, the novel embodiments described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A magnetic storage device comprising:
a substrate; and
a first magnetoresistive effect element and a second magnetoresistive effect element disposed, above the substrate, in an arrangement pattern including a plurality of arrangement areas, each of the first and second magnetoresistive effect elements including a first ferromagnetic layer, a second ferromagnetic layer, a third ferromagnetic layer, a first nonmagnetic layer, and a second nonmagnetic layer, the first nonmagnetic layer being disposed between the first ferromagnetic layer and the second ferromagnetic layer, and the second nonmagnetic layer being disposed between the second ferromagnetic layer and the third ferromagnetic layer and being configured to antiferromagnetically couple the second ferromagnetic layer and the third ferromagnetic layer,
wherein a magnetization orientation of the third ferromagnetic layer of the first magnetoresistive effect element is antiparallel to a magnetization orientation of the third ferromagnetic layer of the second magnetoresistive effect element, and
the first magnetoresistive effect element is disposed in an arrangement area randomly positioned with respect to an arrangement area in which the second magnetoresistive effect element is disposed.

2. The device of claim 1, wherein each of the arrangement areas neighbors another one of the arrangement areas.

3. The device of claim 1, wherein the first magnetoresistive effect element and the second magnetoresistive effect element are arranged in a direction in which the substrate extends.

4. The device of claim 1, wherein magnetization orientations of the first to third ferromagnetic layers are parallel to a film thickness direction.

5. The device of claim 1, further comprising a plurality of third magnetoresistive effect elements each including the first ferromagnetic layer, the second ferromagnetic layer, the third ferromagnetic layer, the first nonmagnetic layer and the second nonmagnetic layer,
wherein each of the plurality of third magnetoresistive effect elements is disposed at random in the remaining arrangement areas in the arrangement pattern.

6. The device of claim 5, wherein magnetization orientations of the third ferromagnetic layers of the plurality of third magnetoresistive effect elements are parallel to the magnetization orientation of the third ferromagnetic layer of the first magnetoresistive effect element or the magnetization orientation of the third ferromagnetic layer of the second magnetoresistive effect element, and are independent from each other.

7. The device of claim 5, wherein the first to third magnetoresistive effect elements are arranged in a direction in which the substrate extends.

8. The device of claim 5, wherein magnetization orientations of the first to third ferromagnetic layers are parallel to a film thickness direction.

9. A manufacturing method of a magnetic storage device, comprising:
forming, above a substrate, a first magnetoresistive effect element and a second magnetoresistive effect element each including a first ferromagnetic layer, a second ferromagnetic layer, a third ferromagnetic layer, a first nonmagnetic layer, and a second nonmagnetic layer, the first nonmagnetic layer being provided between the first ferromagnetic layer and the second ferromagnetic layer, and the second nonmagnetic layer being provided between the second ferromagnetic layer and the third ferromagnetic layer and being configured to antiferromagnetically couple the second ferromagnetic layer and the third ferromagnetic layer;
applying a first magnetic field, which reverses a magnetization orientation of the third ferromagnetic layer of each of the first and second magnetoresistive effect elements, to the formed first and second magnetoresistive effect elements in a first direction; and
applying a second magnetic field in a second direction, which is opposite to the first direction, to the first and second magnetoresistive effect elements to which the first magnetic field was applied.

10. The method of claim 9, wherein the second magnetic field is smaller than the first magnetic field.

11. The method of claim 10, wherein the second magnetic field has such a magnitude as to reverse the magnetization orientation of the third ferromagnetic layer of the first magnetoresistive effect element or the second magnetoresistive effect element.

12. The method of claim 9, further comprising:
determining the second magnetic field; and
applying the determined second magnetic field to manufacture of another magnetic storage device.

13. The method of claim 12, further comprising forming, above the substrate, a plurality of third magnetoresistive effect elements each including the first ferromagnetic layer, the second ferromagnetic layer, the third ferromagnetic layer, the first nonmagnetic layer and the second nonmagnetic layer,
wherein the determining includes determining the second magnetic field, based on the plurality of third magnetoresistive effect elements.

14. The method of claim 13, wherein the plurality of third magnetoresistive effect elements include test patterns.

15. The method of claim 13, wherein the determining includes determining the second magnetic field, based on distribution information in which a magnetic field of a first magnitude, and a ratio of third magnetoresistive effect elements, among the plurality of third magnetoresistive effect elements, in which the magnetization orientations of respective third ferromagnetic layers are reversed by application of the magnetic field of the first magnitude, are associated.

16. The method of claim 15, wherein the determining includes determining, based on the distribution information, the second magnetic field from a range including a magnetic field of such a magnitude as to reverse the magnetization orientations of the third ferromagnetic layers of half the plurality of third magnetoresistive effect elements.

17. The method of claim 12, further comprising forming, above another substrate, a plurality of fourth magnetoresistive effect elements each including the first ferromagnetic layer, the second ferromagnetic layer, the third ferromagnetic layer, and a fourth nonmagnetic layer disposed between the second ferromagnetic layer and the third ferromagnetic layer and configured not to antiferromagnetically couple the second ferromagnetic layer and the third ferromagnetic layer,
wherein the determining includes determining the second magnetic field, based on the plurality of fourth magnetoresistive effect elements.

18. The method of claim 17, wherein the another substrate includes a wafer for evaluation.

19. The method of claim 17, wherein the determining includes determining the second magnetic field, based on distribution information in which a magnetic field of a first magnitude, and a ratio of fourth magnetoresistive effect elements, among the plurality of fourth magnetoresistive effect elements, in which the magnetization orientations of respective third ferromagnetic layers are reversed by application of the magnetic field of the first magnitude, are associated.

20. The method of claim 19, wherein the determining includes determining, based on the distribution information, the second magnetic field from a range including a magnetic field of such a magnitude as to reverse the magnetization orientations of the third ferromagnetic layers of half the plurality of fourth magnetoresistive effect elements.
